(19) United States
(12) Patent Application Publication
(10) Pub. No.: US 2025/0133658 A1
(43) Pub. Date: Apr. 24, 2025

(54) CIRCUIT BOARD SYSTEM

(71) Applicant: Harman Becker Automotive Systems GmbH, Karlsbad (DE)

(72) Inventors: Andreas KUSKA, Rheinstetten (DE); Frank GITZINGER, Straubenhardt (DE); Peter KIES, Karlsruhe (DE); Hichem CHETOUANI, Lingolsheim (FR); Joerg WELKE, Ettlingen-Schöllbronn (DE)

(73) Assignee: Harman Becker Automotive Systems GmbH, Karlsbad (DE)

(21) Appl. No.: 18/921,357

(22) Filed: Oct. 21, 2024

(30) Foreign Application Priority Data
Oct. 19, 2023 (DE) 10 2023 128 796.6

(51) Int. Cl. H05K 1/14; H05K 1/02; H05K 1/18

(52) U.S. Cl. CPC H05K 1/141; H05K 1/0203; H05K 1/144; H05K 1/181; H05K 2201/10015; H05K 2201/10159; H05K 2201/10719; H05K 2201/10734

(57) ABSTRACT

According to an aspect of the present disclosure, there is provided a circuit board system including: a main board having a top side and a bottom side, wherein the main board has at least one cavity on its top side; a printed circuit board, PCB having a top side and a bottom side; and at least one first electronic component arranged on the top side of the PCB, and at least one second electronic component arranged on the bottom side of the PCB, wherein the PCB is arranged on the top side of main board, and wherein the at least one second electronic component on the bottom side of the PCB extends into the cavity on the top side of the main board.

### CROSS-REFERENCE TO RELATED APPLICATIONS

This application claims priority to DE application Serial No. 102023128796.6 filed Oct. 19, 2023, the disclosure of which is hereby incorporated in its entirety by reference herein.

### TECHNICAL FIELD

The present disclosure relates to a circuit board system.

### BACKGROUND

Modular circuit board systems with electrically interconnected circuit boards are becoming more and more popular as the modularity of such arrangements allows swiftly adapting existing technologies. An exemplary circuit board system is described in US 2014/0063748 A1.

In many conventional circuit board systems, the connections between individual circuit boards are implemented as plug-in connections. However, plug-in technology is expensive as such a technology requires plugs and sockets. Aside from that, plug and socket technology occupies a lot of space on the circuit boards. If, on the other hand, soldered connections are used instead of plug-in technology, the operating temperature of the system is limited in range and/or cycles. At increased temperatures and temperature cycles, the failure probability is significantly higher than for systems that use plug-in technology. At the same time, there is a need to maintain or reduce the dimensions of circuit board systems.

Hence there is a need for an improved circuit board system.

### SUMMARY

In the following, each of the described systems, devices, apparatuses, examples, and

The present disclosure relates to a circuit board system with two or more electrically connected circuit boards, wherein one or more cavities are formed in one or more of the circuit boards. The cavities are arranged to accommodate electronic components arranged on one of the circuit boards. The cavities enable arranging electronic components on opposite surfaces of the circuit boards and to decouple the cooling of components on the opposite surfaces. The circuit boards may be electrically connected to one another by a land grid array (LGA) or a ball grid array (BGA).

According to a first aspect of the present disclosure, there is provided a circuit board system including: a main board having a top side and a bottom side, wherein the main board has at least one cavity on its top side; a printed circuit board, PCB having a top side and a bottom side; and at least one first electronic component arranged on the top side of the PCB, and at least one second electronic component arranged on the bottom side of the PCB, wherein the PCB is arranged on the top side of main board, and wherein the at least one second electronic component on the bottom side of the PCB extends into the cavity on the top side of the main board.

This arrangement enables implementing an LGA-module, for example, as a dual-side assembly. Such LGA-module may have a System on Chip (SoC) and one or more Power Management ICs (PMICs) on one side of the PCB, and memory modules (memory ICs) arranged next to the SoC on the opposite side of the PCB. Passive electronic components may be placed underneath the SoC on the same side of the PCB as the memory modules. These components (memory modules, passive components) may be received in openings in a main board that is electrically coupled to the PCB through an LGA. The dimensions and positions of the openings are variable and may be made dependent on the component size.

In contrast to conventional LGA-modules implemented as single-side assemblies with a common heat-sink for the SoC, PMICs, memory and power controller, the dual side assembly according to embodiments of the present disclosure enables, among other things, decoupling a heat sink for the SoC and/or PMICs, on the one hand, and a heat sink for other components such as memory, on the other hand. In other words, the SoC and/or PMICs and the memory may each be coupled to its own heat sink. Such decoupling of the heat sink is a significant improvement in terms of dealing with the increasing power consumption of the latest SoC generations.

The dual-side assembly according to embodiments of the present disclosure enables the use of low temperature grade memory. Also, the removal/omission of components saves space on the SoC side of the PCB, thereby enabling improved layout-designs. In addition, the assembly can be implemented as an LGA-type module without requiring (expensive) connectors. Further, due to the spatial isolation between the main heat sources, namely the SoC on one side and memory on the other side, the heat sink design(s) can be simplified.

In an embodiment, the at least one cavity extends through the main board from the top side to the bottom side thereof. In other words, the at least one cavity is implemented as a through-opening in the main board. Accordingly, an electrical component on the bottom side of the PCB can extend through and beyond the bottom surface of the main board.

In an embodiment, the circuit board system includes a plurality of said second electronic components arranged on the bottom side of the PCB; and a plurality of cavities on the top side of the main board, wherein the cavities are arranged to match the locations of and receive the second electronic components at the bottom of the PCB. Accordingly, the main board can be tailored to accommodate electronic components at the bottom side of the PCB while retaining a sufficiently large surface for an LGA- or BGA-type electrical connection between the PCB and the main board.

In an embodiment, the circuit board system includes a plurality of said second electronic components arranged on the bottom side of the PCB, wherein one or more but not all of the second electronic components extend into one or more corresponding ones of said at least one cavity. In other words, cavities may be provided for accommodating selected ones of the electronic components arranged at the bottom side of the PCB. For example, some of the electronic components may have larger vertical dimensions (i.e., project further from the PCB's bottom surface) than others. Cavities may be provided for those larger components, while there may already be sufficient space between the PCB and the main board for accommodating the other (smaller) components.

In an embodiment, the PCB is connected to the main board through an LGA. An LGA-type connection may be employed to reduce the overall vertical dimensions of the circuit board system.

In an alternative embodiment, the PCB is connected to the main board through a BGA. In a BGA-type connection, there may be more space between the PCB and the main board. This space may be sufficient to accommodate some of the components at the bottom side of the PCB without requiring corresponding cavities in the main board.

In an embodiment, the at least one first electronic component is attached to a heat sink at the top side of the PCB. Thus, the at least one first electronic component, e.g., an SoC, has its own heat sink isolated from a heat sink that may be provided for electronic components (e.g., memory) provided at the bottom side of the PCB.

In an embodiment, the at least one second electronic component is attached to a heat sink, heat spreader, chassis cover or metal-sheet cover at the bottom side of the PCB. Accordingly, electronic components arranged at the bottom side of the PCB may (also) have their own heat sink, or heat dissipation may be provided for by other mechanisms, for example, through connection to a chassis cover or metal-sheet cover of a device in which the circuit board system is mounted. Thus, it is possible to use existing elements for heat dissipation. Such elements may have a lower heat dissipation than dedicated heat sinks, but this may be sufficient, as the electronic components at the bottom side of the PCB produce less heat and are thermally uncoupled from the electronic components (e.g., an SoC) at the top side of the PCB that may produce more heat.

In an embodiment, the at least one second electronic component is attached to the heat sink, heat spreader, chassis cover or metal-sheet cover through a thermally conductive mold compound or resin. Accordingly, the at least one second electronic component may be thermally coupled to elements which are not directly adjacent (in contact) with them.

In an embodiment, the at least one first electronic component includes an SoC. The at least one first electronic component may also include one or more PMICs. The at least one second electronic component may include one or more DRAMs and/or one or more multilayer ceramic chip capacitors, MLCCs.

The at least one second electronic component may include one or more passive electronic components arranged on the bottom side of the PCB opposite to an SoC arranged on the top side of the PCB. Passive electronic components such as MLCCs do not generate additional heat and/or are sufficiently resistant to heat that may emanate from the SoC and are thus well suited for an arrangement underneath the SoC. This arrangement makes efficient use of the available PCB space.

In an embodiment, the PCB includes a plurality of said cavities in the main board and one or more bridges between said cavities. The bridges between the cavities improve the rigidity of the main board. Also, the bridges may be used to arrange pins, pads or balls thereon for connecting the PCB to the main board. This arrangement makes efficient use of the available space for electrical connections between the main board and the PCB.

### BRIEF DESCRIPTION OF THE DRAWINGS

Example embodiments of the disclosure will be described, by way of example only, with reference to the accompanying drawings in which:

FIG. 1 schematically shows a top view of a main board PCB for use in a circuit board system according to an embodiment of the present disclosure;

FIG. 2 schematically shows a top view of a circuit board system according to an embodiment of the present disclosure;

FIG. 3 schematically shows a cross section through the circuit board system of FIG. 2;

FIG. 4 schematically shows a top view of another main board PCB for use in a circuit board system according to an embodiment of the present disclosure;

FIG. 5 schematically shows a cross section through a circuit board system according to an embodiment of the present disclosure;

FIG. 6 schematically shows a cross section through a circuit board system according to another embodiment of the present disclosure;

FIG. 7 schematically shows a cross section through a circuit board system according to another embodiment of the present disclosure; and

FIG. 8 schematically shows a bottom view of a PCB for use in a circuit board system according to an embodiment of the present disclosure.

### DETAILED DESCRIPTION

There now follows, by way of example only, a description of exemplary embodiments of the present disclosure. These examples are described in reference to the figures identified above, which are included to provide further detail and clarity. It should be understood that the examples described herein are not limiting, and that other examples falling within the scope of the claims are envisaged.

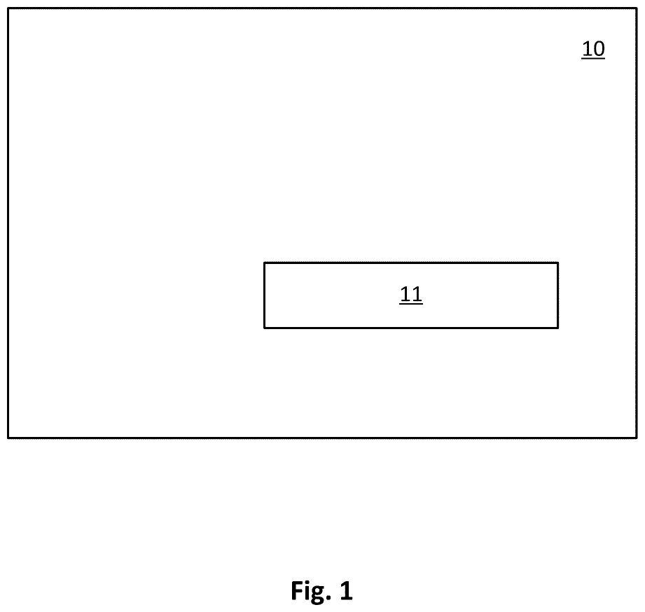

FIG. 1 schematically illustrates a top view of a main board 10 for use in a circuit board system according to an embodiment of the present disclosure. The main board 10 includes a cavity 11 on a top surface thereof. The cavity 11 can be formed by a recess or extend through the entire thickness of the main board 10. The cavity 11 is to receive one or more electronic components arranged on a bottom surface of a PCB, as described below.

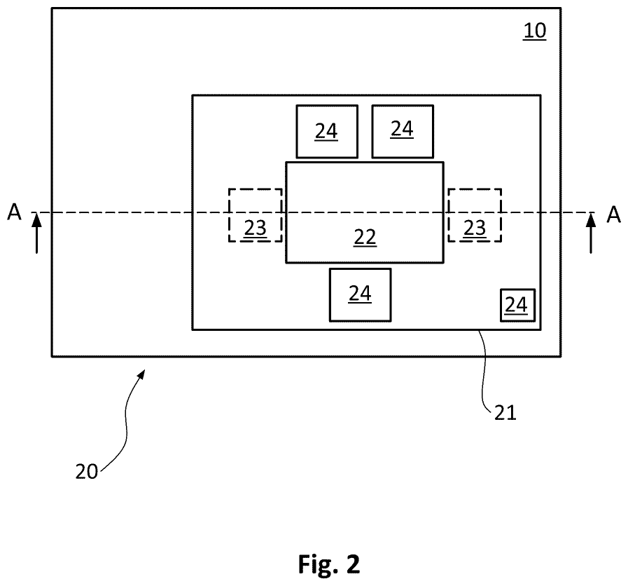

FIG. 2 schematically illustrates a top view of a circuit board system 20 according to an embodiment of the present disclosure. The circuit board system 20 includes the main board 10 and a PCB 21 arranged on the top surface of the main board 10 above the cavity 11 shown in FIG. 1. The PCB 21 includes one or more first electronic components arranged on a top surface thereof. For example, the first electronic components may include a system on chip (SoC) 22 and PMICs 24. The PCB 21 also includes one or more second electronic components arranged on a bottom surface thereof. For example, the second electronic components may include DRAMs 23, shown in dashed lines. It is noted that the present disclosure is not limited to any particular types, combination or arrangement of electronic components on the top and bottom surfaces of the PCB 21.

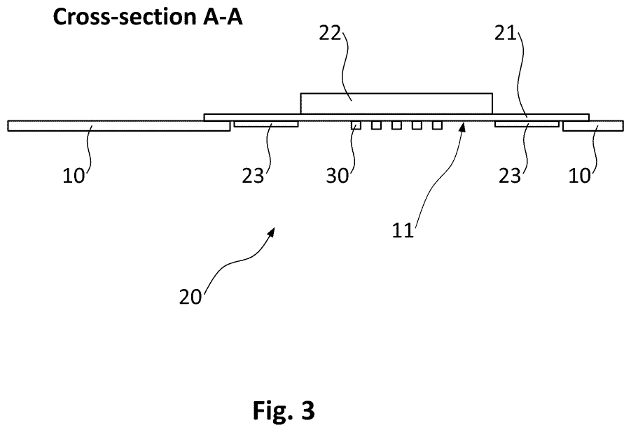

FIG. 3 schematically shows a cross section through the circuit board of FIG. 2 along line A-A. The PCB 21 has second electronic components arranged on its bottom surface. In the illustrated embodiment, the second electronic components include the DRAMs 23 and a plurality of passive electronic components 30, for example, multilayer ceramic chip capacitors (MLCCs). The passive electronic components 30 are arranged opposite the SoC 22 arranged on the top surface of the PCB 21.

FIG. 3 also illustrates the cavity 11 extending through the main board 10. The PCB 21 is arranged on the top surface of the main board 10 such that the second electronic components (DRAMs 23 and MLCCs) at the bottom of the PCB 21 extend into the cavity 21. Accordingly, the circuit board system 20 according to the illustrated embodiment has a reduced overall thickness.

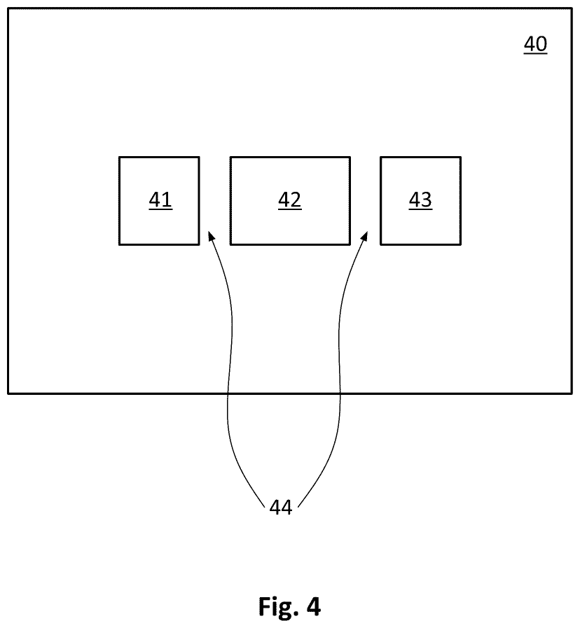

FIG. 4 schematically shows a top view of a main board 40 for use in a circuit board system according to another embodiment of the present disclosure. In this embodiment, the main board 40 includes three cavities 41, 42 and 43. However, the present disclosure is not limited in this regard, and the main board may include any number and arrangement of cavities. Also, the cavities may be formed by through-openings or recesses or any combination thereof.

Between the cavities 41, 42 and 43, the main board 40 includes bridges 44. Accordingly, in this embodiment, instead of a single, large cavity (cavity 11 of FIG. 1), the main board 40 has a plurality of cavities 41, 42 and 43 separated by the bridges 44. The bridges 44 improve the rigidity and stability of the main board 40 and provide space for electrical connections, for example, for electrical connections through solder balls or pads.

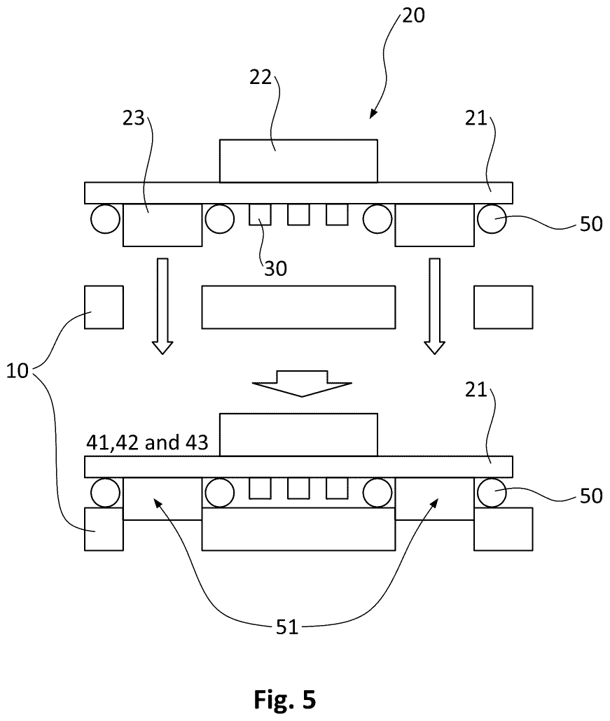

FIG. 5 schematically shows a cross section through a circuit board system 20 according to an embodiment of the present disclosure. In this embodiment, the circuit board system 20 includes a ball grid array (BGA) 50 for electrically connecting the PCB 21 with the main board 10. The vertical extension of the BGA 50 is higher than the vertical extension of the passive electronic components 30. Accordingly, as shown in the lower section of FIG. 5, the passive electronic components 30 are received in a space between the main board 10 and the PCB 21. In other words, in this embodiment, no cavity within the main board 10 is provided for accommodating the passive electronic components 30. On the other hand, the vertical extension of the BGA 50 is lower than the vertical dimensions of the DRAMs 23. To accommodate the DRAMs 23, the main board 10 includes cavities 51, one for each DRAM 23. Therefore, the overall vertical dimensions of the circuit board system 20 can be maintained despite arranging the DRAMs 23 at the bottom side of the PCB 21 facing the main board 10.

It is noted that any number of cavities 51 can be provided within the main board 10 to accommodate any type of active or passive electronic components arranged at the bottom side of the PCB 21.

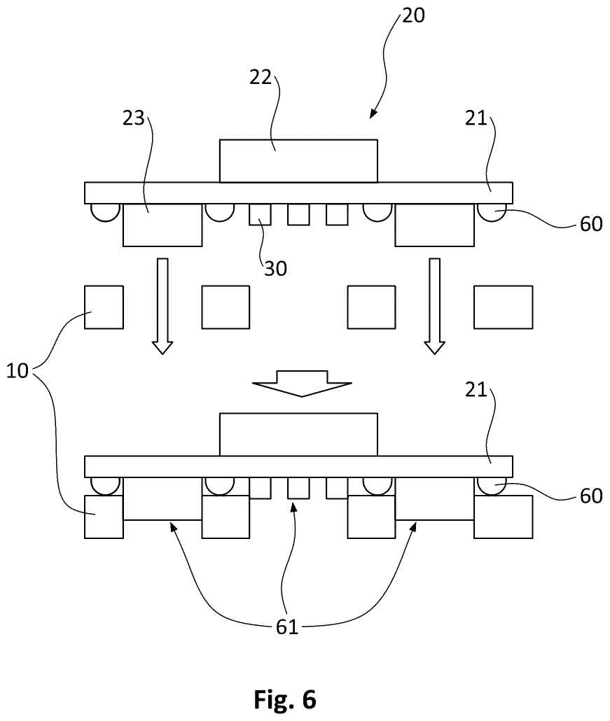

FIG. 6 schematically shows a cross section through a circuit board system 20 according to another embodiment of the present disclosure. In this embodiment, instead of the BGA 50, the circuit board system 20 includes an LGA 60 for electrically connecting the PCB 21 with the main board 10. One difference between BGAs and LGAs is that LGAs have reduced vertical dimensions. Accordingly, the space between PCB 21 and the main board 10 may not be sufficient to accommodate the passive electronic components 30. Therefore, to provide sufficient space, three cavities 61 including an additional central cavity (compared to the embodiment of FIG. 5) are provided to accommodate the DRAMs 23 and the passive electronic components 30. Again, it is noted that the present disclosure is not limited to the illustrated, exemplary number and combination of electronic components and cavities. Rather, the present disclosure envisages any number and arrangements of cavities in the main board 10 to accommodate any type of electronic components at the bottom of the PCB.

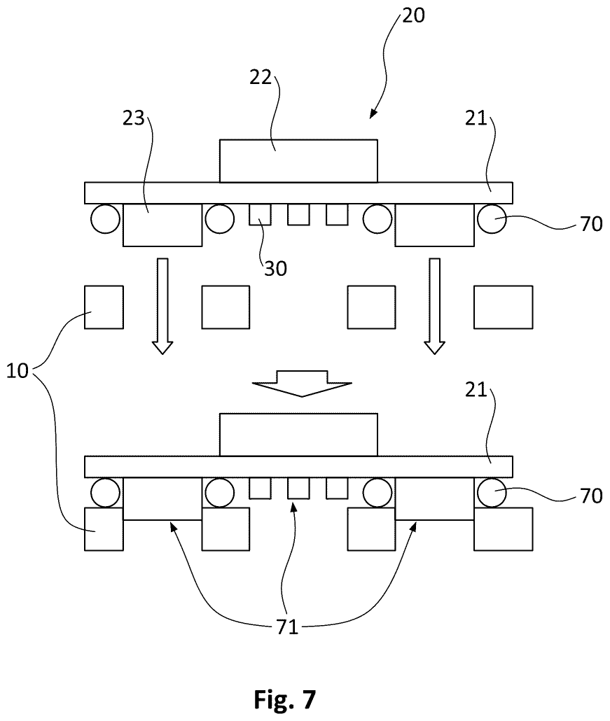

FIG. 7 schematically shows a cross section through a circuit board system 20 according to yet another embodiment of the present disclosure. Essentially, this embodiment combines features from the embodiments of FIGS. 5 and 6 in that the circuit board system 20 includes a BGA 70 together with a central cavity 71 underneath the passive electronic components 30 at the bottom of the PCB 21, along with two cavities 71 for accommodating the DRAMs 23. Although the central cavity 71 is not necessary for accommodating the passive electronic components, it may nevertheless be advantageous because it enables also using the main board 10 in LGA-based systems. In other words, the main board is suitable for use in both BGA- and LGA-type assemblies. In addition, the central cavity 71 reduces the weight and material requirements for the main board 10. Also, this embodiment enables reducing the diameter of the balls of the BGA 70 to an extent that the passive electronic components 30 do extend into the central cavity 71. In other words, this embodiment provides versatility in terms of how the main board is implemented and used.

Again, it is noted that the present disclosure is not limited to the illustrated, exemplary number and combination of electronic components and cavities.

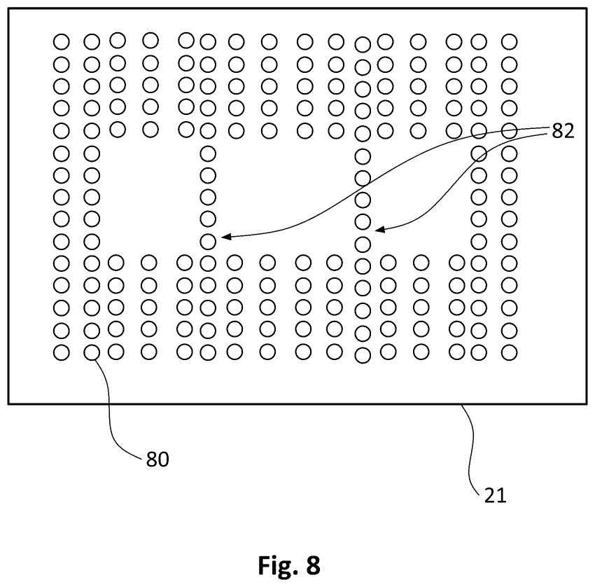

FIG. 8 schematically shows a bottom view of a PCB 21 for use in a circuit board system 20 according to an embodiment of the present disclosure. The printed circuit board 21 includes a BGA 80. The balls of the BGA 80 are arranged to cover large parts of the bottom side of the PCB 21, including areas 82 which lie on top of the bridges 44 (FIG. 4) between the cavities in the main board 10. Alternatively, instead of the BGA 80, an LGA may be provided.

What is claimed is:

1. A circuit board system comprising:
a main board having a top side and a bottom side, wherein the main board has at least one cavity on the top side thereof;
a printed circuit board (PCB) having a top side and a bottom side; and
at least one first electronic component arranged on the top side of the PCB, and at least one second electronic component arranged on the bottom side of the PCB,
wherein the PCB is arranged on the top side of main board, and
wherein the at least one second electronic component on the bottom side of the PCB extends into the at least one cavity on the top side of the main board.

2. The circuit board system of claim 1, wherein the at least one cavity extends through the main board from the top side to the bottom side.

3. The circuit board system of claim 1 comprising:
a plurality of the second electronic components arranged on the bottom side of the PCB; and
a plurality of cavities on the top side of the main board, wherein the plurality of cavities is arranged to match locations of and receive the plurality of the second electronic components at the bottom side of the PCB.

4. The circuit board system of claim 1 comprising:
a plurality of the second electronic components arranged on the bottom side of the PCB, wherein one or more of the second electronic components extend into one or more corresponding ones of the at least one cavity.

5. The circuit board system of claim 1, wherein the PCB is connected to the main board through a ball grid array (BGA).

6. The circuit board system of claim 1, wherein the PCB is connected to the main board through a land grid array (LGA).

7. The circuit board system of claim 1, wherein the at least one first electronic component is attached to a heat sink at the top side of the PCB.

8. The circuit board system of claim 1, wherein the at least one second electronic component is attached to a heat sink, heat spreader, chassis cover or metal-sheet cover at the bottom side of the PCB.

9. The circuit board system of claim 8, wherein the at least one second electronic component is attached to the heat sink, heat spreader, chassis cover or metal-sheet cover through a thermally conductive mold compound or resin.

10. The circuit board system of claim 1, wherein the at least one first electronic component comprises a system on chip (SoC).

11. The circuit board system of claim 10, wherein the at least one second electronic component comprises one or more passive electronic components arranged on the bottom side of the PCB opposite to the SoC that is arranged on the top side of the PCB.

12. The circuit board system of claim 1, wherein the at least one second electronic component comprises one or more dynamic random-access memories and/or one or more multilayer ceramic chip capacitors (MLCCs).

13. The circuit board system of claim 1, wherein the PCB comprises a plurality of the cavities and one or more bridges positioned between the cavities.

14. The circuit board system of claim 13, comprising a plurality of pins, pads or balls on the one or more bridges for connecting the PCB to the main board.

15. A circuit board system comprising:
a main board having a top side and a bottom side, wherein the main board has at least one cavity on the top side thereof;
a printed circuit board (PCB) having a top side and a bottom side; and
at least one first electronic component arranged on the top side of the PCB, and at least one second electronic component arranged on the bottom side of the PCB,
wherein the PCB is positioned on the main board, and
wherein the at least one second electronic component on the bottom side of the PCB extends into the at least one cavity on the top side of the main board.

16. The circuit board system of claim 15, wherein the at least one cavity extends through the main board from a top side of the main board to the bottom side.

17. The circuit board system of claim 15 further comprising:
a plurality of the second electronic components arranged on the bottom side of the PCB; and
a plurality of cavities on the top side of the main board, wherein the plurality of cavities are arranged to match locations of and receive the plurality of the second electronic components at the bottom side of the PCB.

18. The circuit board system of claim 15 further comprising:
a plurality of the second electronic components arranged on the bottom side of the PCB, wherein one or more of the second electronic components extend into one or more corresponding ones of the at least one cavity.

19. The circuit board system of claim 15, wherein the PCB is connected to the main board through a ball grid array (BGA).

20. A circuit board system comprising:
a main board having a first side and a second side, wherein the main board has at least one cavity on the first side thereof;
a printed circuit board (PCB) having a first side and a second side; and
at least one first electronic component arranged on the first side of the PCB, and at least one second electronic component arranged on the second side of the PCB,
wherein the PCB is arranged on the first side of positioned on the main board, and
wherein the at least one second electronic component on the second side of the PCB extends into the at least one cavity on the first side of the main board.
